(19) United States
(12) Patent Application Publication
(10) Pub. No.: US 2002/0001325 A1
(43) Pub. Date: Jan. 3, 2002

(54) Semiconductor laser device with optical waveguide exhibiting high kink output

(75) Inventor: Toshiaki Igarashi, Tokyo (JP)

Correspondence Address: YOUNG & THOMPSON, 745 SOUTH 23RD STREET 2ND FLOOR, ARLINGTON, VA, 22202

(73) Assignee: NEC Corporation

(21) Appl. No.: 09/861,660

(22) Filed: May 22, 2001

(30) Foreign Application Priority Data
May 25, 2000 (JP) 2000-155266

(51) Int. Cl. H01S 5/00

(52) U.S. Cl. 372/43

(57) ABSTRACT

A semiconductor laser device has at least an active layer and an optical waveguide region, which includes at least a part of the active layer, wherein Δ_{gain}/Γ is at least 85 [cm⁻¹/%], where Δ_{gain} [cm⁻¹] is a difference in gain between a zero-order fundamental mode and a one-order high-order mode in a lateral transverse mode of the optical wvaveguide, and Γ [%] is a total optical confinement rate of the at least part of the active layer in the zero-order fundamental mode.

### BACKGROUND OF THE INVENTION

1. Field of the Invention

The present invention relates to a semiconductor laser device, and more particularly to a semiconductor laser device with an optical waveguide exhibiting a high kink output.

2. Description of the Related Art

The semiconductor laser device shows a non-linearity on variation of optical output versus injection current, namely the non-linearity of output-current characteristic. Such a non-linearity will be referred to as “kink”. An output, where kink appears, will be referred to as “kink output”. When the kink appears, a near field pattern may be deformed or translated, whereby a coupling coefficient is reduced. The kink effect reduces the coupling coefficient, even a high coupling coefficient is needed for obtaining a high output.

A conventional semiconductor laser device, which has a self-aligned structure for emitting a laser beam of 0.98 micrometers wavelength, is disclosed in Japanese laid-open patent publication No. 10-200201. The device has an n-AlGaAs current blocking layer, which varies an aluminum-compositional ratio in layer-thickness direction for optimizing the kink output. As the aluminum-compositional ratio is reduced, a difference in equivalent refractive index or effective refractive index is reduced, whereby the kink output is increased. The reduction in such a compositional ratio deteriorates device characteristics under high temperature. An optimum aluminum-compositional index is 0.39, where the kink output is 250 mW at an operating temperature of 25° C. A further increase in the kink output from 250 mW is, however, advantageous for the advanced laser device.

In the above circumstances, the development of a novel semiconductor laser device having an improved optical waveguide structure, which makes the device free from the above problems, is desirable.

### SUMMARY OF THE INVENTION

Accordingly, it is an object of the present invention to provide a novel semiconductor laser device having an improved optical waveguide structure in a manner that avoid the problems of the prior art.

It is a further object of the present invention to provide a novel semiconductor laser device having an improved optical waveguide structure, allowing the device to show high kink output.

It is another object of the present invention to provide a novel a semiconductor laser device having at least an active layer and an optical waveguide region, which includes at least a part of the active layer, wherein Δ_{gain}/Γ is at least 85 [cm⁻¹/%], where Δ_{gain} [cm⁻¹] is a difference in gain between a zero-order fundamental mode and a one-order high-order mode in a lateral transverse mode of the optical waveguide, and Γ [%] is a total optical confinement rate of the at least part of the active layer in the zero-order fundamental mode.

These objects and other objects, features and advantages of the present invention will be apparent from the following description of preferred embodiments.

### BRIEF DESCRIPTION OF THE DRAWINGS

Preferred embodiments according to the present invention will be described in detail with reference to the accompanying drawings.

FIG. 1 is a fragmentary cross sectional elevation view of a semiconductor laser device having an improved optical waveguide structure and a separate confinement hetero-structure active layer in accordance with the present invention.

FIG. 2 is a fragmentary cross sectional elevation view of a semiconductor laser device with an improved optical waveguide structure in combination with a diagram illustrative of a refractive index profile in an optical waveguide region of a stripe-shaped plan region in a first embodiment in accordance with the present invention.

FIG. 3 is a fragmentary cross sectional elevation view of a semiconductor laser device with an improved optical waveguide structure in combination with a diagram illustrative of a refractive index profile in an optical waveguide region of a stripe-shaped plan region in a second embodiment in accordance with the present invention.

FIG. 4 is a fragmentary cross sectional elevation view of a semiconductor laser device with an improved optical waveguide structure in combination with a diagram illustrative of a refractive index profile in an optical waveguide region of a stripe-shaped plan region in a third embodiment in accordance with the present invention.

FIG. 5 is a fragmentary cross sectional elevation view of a semiconductor laser device with a conventional optical waveguide structure in combination with a diagram illustrative of a refractive index profile in an optical waveguide region of a stripe-shaped plan region in a comparative example 1.

FIG. 6 is a fragmentary cross sectional elevation view of a semiconductor laser device with a conventional optical waveguide structure in combination with a diagram illustrative of a refractive index profile in an optical waveguide region of a stripe-shaped plan region in a comparative example 2.

FIG. 7 is a diagram illustrative of kink output versus Δ_{gain}/Γ of the semiconductor laser devices in the first to third embodiments and the comparative examples 1 and 2.

FIG. 8 is a diagram illustrative of kink output versus Δ_{gain}, transformed from FIG. 7, wherein a lateral axis is translated from Δ_{gain}/Γ to Δ_{gain} .

### DETAILED DESCRIPTION OF THE PREFERRED EMBODIMENTS

A first aspect of the present invention is a semiconductor laser device having at least an active layer and an optical waveguide region, which includes at least a part of the active layer, wherein Δ_{gain}/Γ is at least 85 [cm^{-1/}%], where Δ_{gain} [cm⁻¹] is a difference in gain between a zero-order fundamental mode and a one-order high-order mode in a lateral transverse mode of the optical waveguide, and Γ[%] is a total optical confinement rate of the at least part of the active layer in the zero-order fundamental mode.

If only the mode gain difference Δ_{gain} is increased, then it is uncertain that the kink output is increased. If both the mode gain difference Δ_{gain} and the optical confinement rate Γ are increased, then the kink output is not increased. If the mode gain difference Δ_{gain} is increased and the optical confinement rate Γ is decreased, then the kink output is increased. Accordingly, in order to obtain an increased kink output, it is essential that Δ_{gain}/Γ is increased.

In this specification, the zero-order mode is defined to be fundamental mode, and the one-order mode is defined to be high-order mode. Namely, the zero-order mode as the fundamental mode will, hereinafter, be referred to as “zero-order fundamental mode”, and the one-order mode as the high-order mode will, hereinafter, be referred to as “one-order high-order mode”.

At least one active layer may comprises plural active layers, and the Γ [%] is a total sum of individual optical confinement rates of the plural active layers. Each of the plural active layers in the optical waveguide region has an individual optical confinement rate. If the device has plural active layers such as multiple quantum well layers, then the Γ [%] is the total sum of individual optical confinement rates of the plural active layers.

The plural active layers may comprise multiple quantum well layers, and the at least part of each of the multiple quantum well layers has an optical confinement rate of at most 0.5% in the zero-order fundamental mode.

At least one active layer may have a separate confinement hetero-structure, and the Γ [%] is an optical confinement rate of the at least part of the separate confinement hetero-structure.

For obtaining the high Δ_{gain}/Γ of at least 85 [cm⁻¹/%], the optical waveguide region may have a symmetrical refractive index profile with reference to the at least one active layer in a vertical direction to interfaces of the at least one active layer. Alternatively, the optical waveguide region may have an asymmetrical refractive index profile with reference to the at least one active layer in a vertical direction to interfaces of the at least one active layer In the asymmetrical refractive index profile, for obtaining the Δ_{gain}/Γ of at least 85 [cm^{31 1}/%], the device may have an n-side region and a p-side region, which are separated by the at least one active layer, and the asymmetrical refractive index profile is that the n-side region is higher than the p-side region in an integrated value of a refractive index in the vertical direction.

At least a cladding region may optically be provided adjacent to at least one interface of the at least one active layer, and wherein the at least cladding region comprises a plural-layered structure, which includes at least an optical confinement layer. The plural-layered structure comprises plural cladding layers different in refractive index. The layer higher in refractive index serves as the optical confinement layer. Adjustment to variations in refractive index among the plural cladding layers adjusts the lateral transverse mode in the at least one active layer, thereby obtaining the increased value of the mode gain difference Δ_{gain.}

The cladding region may optionally comprise p-side and n-side cladding regions adjacent to opposite surfaces of the at least one active layer, and the p-side and n-side cladding regions comprise first and second plural-layered structures respectively, and each of the first and second plural-layered structures includes at least an optical confinement layer. The first plural-layered structure comprise a first set of plural cladding layers different in refractive index, The layer higher in refractive index serves as the optical confinement layer. The second plural-layered structure compnse a second set of other plural cladding layers different in refractive index. The layer higher in refractive index serves as the optical confinement layer. Adjustment to variations in refractive index among the plural cladding layers adjusts the lateral transverse mode in the at least one active layer, thereby obtaining the increased value of the mode gain difference Δ_{gain}. Both a uniform adjustment or different adjustments to the first and second plural-layered structures may be possible for obtaining the high Δ_{gain}Γ. Notwithstanding, different adjustments to the first and second plural-layered structures are preferable.

At least one active layer and the p-side and n-side cladding regions may have a symmetrical refractive index profile with reference to the at least one active layer in a vertical direction to the interfaces of the at least one active layer for obtaining the high Δ_{gain}/Γ.

At least one active layer and the p-side and n-side cladding regions may have an asymmetrical refractive index profile with reference to the at least one active layer in a vertical direction to the interfaces of the at least one active layer for obtaining the high Δ_{gain}/Γ.

In the above case of the asymmetrical refractive index profile, the asymmetrical refractive index profile may be that the n-side cladding region is higher than the p-side cladding region in an integrated value of a refractive index in the vertical direction for obtaining the high Δ_{gain}/Γ.

The device may have a ridged waveguide structure, and a partial region of the at least one active layer is included in the optical waveguide region.

Further, current blocking layers may optionally be provided in both sides of the ridged waveguide structure.

The device may optionally have a self-aligned structure, and a partial region of the active layer may be included in the optical waveguide region.

The device may optionally have current confinement layers in both sides of the at least one active layer, and substantially all regions of the active layer may be included in the optical waveguide region.

The device further may optionally have a bottom cladding region under the at least one active layer; a top cladding region over the at least one active layer, and the top cladding region having a stripe-shaped region, which defines the optical waveguide region; and current blocking layers adjacent to both sides of the stripe-shaped region.

In the above case, the optical waveguide region may be a ridge-type optical waveguide.

In the above case, the optical waveguide region may be a self-aligned structure optical waveguide.

In the above case, the bottom cladding region may optionally have a first multi-layered structure comprising plural layers different in reflexive index, and the top cladding region may optionally have a second multi-layered structure comprising other plural layers different in reflexive index.

In accordance with the present invention, Δ_{gain}/Γ is an important factor for the kink output. The optical waveguide is designed so that Δ_{gain}/Γ is high, for example, at least 85 [cm⁻¹/%], where Δgain [cm^{31 1}] is a gain difference between a zero-order fundamental mode and a one-order high-order mode in a lateral transverse mode of the optical waveguide, and Γ[%] is a total optical confinement rate of the at least part of the active layer in the zero-order fundamental mode. If the laser device has a single active layer, then the total optical confinement rate is an optical confinement rate of the part of the single active layer in the optical waveguide region. If the laser device has plural active layers, then the total optical confinement rate is the sum of individual optical confinement rates of the parts of the plural active layers in the optical waveguide region.

The present inventor could first discover that Δ_{gain}/Γ is the important factor for the kink output. Before the present invention was invented, it had been known that the mode gain difference Δ_{gain} is one factor for the kink output. The present inventor could first confirm that the kink output depends on not only the mode gain difference Δ_{gain} but also the optical confinement rate Γ. If the optical confinement rate Γ is large, such a large Γ cancels the effect of the large modc gain difference Δ_{gain}. If the mode gain difference Δgain is large and the optical confinement rate Γ is small, then the large kink output is obtained.

In order to increase Δ_{gain}/Γ, various design measures are available. For example, a multi-layered structure of the cladding layer and an asymmetrical optical waveguide structure may be effective. If the cladding layer comprises compositionally different plural layers, then a highest refractive index layer serves as an optical confinement layer in the cladding layer. The optical confinement rate of the optical confinement layer is made different between inside and outside of the optical waveguide region, for accurately adjusting the lateral transverse mode of the active layer so as to increase the mode gain difference Δ_{gain}.

The above feature of the present invention is more effective if applied to preferable structures that the top cladding region has a stripe-shaped selected region, both sides of which are adjacent to current blocking layers for current confinement into the stripe-shaped selected region. A ridge-shaped optical waveguide structure and a self-aligned optical waveguide structure are typical examples of the above structures. The ridge-shaped optical waveguide structure has a ridge-shaped top cladding layer or a mesa-structurcd top cladding layer. The stripe-shaped selected region of the top cladding layer defines the optical waveguide region.

In the above preferable structures, the active layer extends entirely over a substrate. Namely, the active layer extends not only inside of the optical waveguide region but also outside thereof. The top cladding layer having the stripe-shaped region is provided over the active layer. A longitudinal direction of the stripe-shaped region is parallel to a light-propagating direction of the optical waveguide. Since the current blocking layers extend both sides of the stripe-shaped region, an injection current is confined to tlhe stripe-shaped region by the current blocking layers.

The device may further comprises: a bottom cladding region under the at least one active layer, the bottom cladding region comprising a first plural-layered structure different in refractive index and including at least a first optical confinement cladding layer having a higher refractive index ; and a top cladding region over the at least one active layer, the top cladding region also having a ridge structure having a stripe-shape region which defines the optical waveguide region, and the top cladding region comprising a second plural-layered structure different in refractive index and including at least a second optical confinement cladding layer having a higher refractive index, and the second optical confinement cladding layer selectively extending in the ridge structure, wherein an inside of the optical waveguide region has a symmetrical refractive index profile with reference to the at least one active layer in a vertical direction to surfaces of the at least one active layer, whilst an outside of the optical waveguide region has an asymmetrical refractive index profile with reference to the at least one active layer in the vertical direction.

Current blocking layers may be provided adjacent to both sides of the ridge structure.

The device may further comprise: a bottom cladding region under the at least one active layer, the bottom cladding region comprising a first plural-layered structure different in refractive index and including at least a first optical confinement cladding layer having a higher refractive index; and a top cladding region over the at least one active layer, the top cladding region also having a ridge structure having a stripe-shape region which defines the optical waveguide region, and the top cladding region comprising a second plural-layered structure different in refractive index and including at least a second optical confinement cladding layer having a higher refractive index, and the second optical confinement cladding layer selectively extending in the ridge structure, wherein an inside of the optical waveguide region has a symmetrical optical confinement rate profile with reference to the at least one active layer in a vertical direction to surfaces of the at least one active layer, whilst an outside of the optical waveguide region has an asymmetrical optical confinement rate profile with reference to the at least one active layer in the vertical direction, and wherein the inside of the optical waveguide region is higher than the outside of the optical waveguide region in an optical confinement rate of the at least one active layer.

A second aspect of the present invention is a semiconductor laser device, which comprises: at least an active layer; a bottom cladding region under the at least one active layer, the bottom cladding region comprising a first plural-layered structure different in refractive index and including at least a first optical confinement cladding layer having a higher refractive index; and a top cladding region over the at least one active layer, the top cladding region also having a ridge structure having a stripe-shape region which defines an optical waveguide region, and the top cladding region comprising a second plural-layered structure different in refractive index and including at least a second optical confinement cladding layer having a higher refractive index, and the second optical confinement cladding layer selectively extending in the ridge structure, wherein an inside of the optical waveguide region has a symmetrical refractive index profile with reference to the at least one active layer in a vertical direction to surfaces of the at least one active layer, whilst an outside of the optical waveguide region has an asymmetrical refractive index profile with reference to the at least one active layer in the vertical direction. A third aspect of the present invention is a semiconductor laser device, which comprises: at least an active layer; a bottom cladding region under the at least one active layer, the bottom cladding region comprising a first plural-layered structure different in refractive index and including at least a first optical confinement cladding layer having a higher refractive index ; and a top cladding region over the at least one active layer, the top cladding region also having a ridge structure having a stripe-shape region which defines an optical waveguide region, and the top cladding region comprising a second plural-layered structure different in refractive index and including at least a second optical confinement cladding layer having a higher refractive index, and the second optical confinement cladding layer selectively extending in the ridge structure, wherein an inside of the optical waveguide region has a symmetrical optical confinement rate profile with reference to the at least one active layer in a vertical direction to surfaces of the at least one active layer, whilst an outside of the optical waveguide region has an asymmetrical optical confinement rate profile with reference to the at least one active layer in the vertical direction, and wherein the inside of the optical waveguide region is higher than the outside of the optical waveguide region in an optical confinement rate of the at least one active layer.

The above described present invention provides the following advantages. Not only the optical confinement but also the current confinement are realized, whereby a highly stable lateral transverse mode is also realized. Further, it is easy to control the refractive index of the optical waveguide.

As described above, the active layer extends entirely over the substrate, although the stripe-shaped selected region of the top cladding layer defines the optical waveguide region. It is possible that the active region outside the optical waveguide region receives carrier injections by carrier diffusion and lateral leakage of injection current.

If the injection current is large for high output, then it is possible that a gain be caused in the outside of the stripe-shaped selected region or the optical waveguide region, particularly adjacent regions to the stripe-shaped selected region or the optical waveguide region. This means increasing the width of the effective optical waveguide region which generates the gain, whereby a high-order mode gain may also be increased, resulting in promoting the kink.

In accordance with the present invention, however, the optical waveguide structure has the high value of Δ_{gain}/Γ so that the kink output, which is the critical level for causing the kink effect, is high or increased, for the purpose of avoiding the kink effect, even if the injection current is large for high output. It is essential for the present invention that Δ_{gain}/Γ is at least 85[cm⁻¹/%]. However, Δ_{gain}/Γ is preferably 95 [cm⁻¹/%] or higher, and more preferably 100 [cm⁻¹/%] or higher.

In order to obtain the high Δ_{gain}/Γ, it is necessary that the mode gain difference Δ_{gain} is increased and the optical confinement rate Γ is decreased. The decrease in the optical confinement rate Γ is, actually, however, limited by the lower limit of a slope rate. The decrease in the optical confinement rate Γ decreases the slope rate. An extensive decrease of the slope rate is not preferable. There is the lower limit of the slope rate. The optical confinement rate Γ is decided as low as possible but in consideration of the lower limit of the slope rate. It is, therefore, important that the optical waveguide structure is designed to obtain a large mode gain difference Δgain.

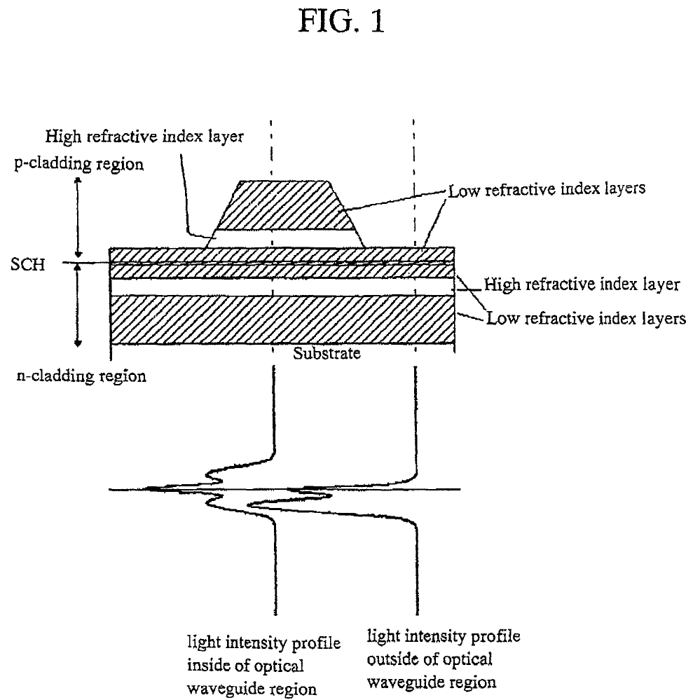

Available method for. designing the optical waveguide will subsequently be described by way of a ridged optical waveguide with reference to FIG. 1. A semiconductor laser device is provided over a substrate. The semiconductor laser device has an n-side bottom cladding region over the substrate, a separate confinement hetero-structure active layer over the n-side bottom cladding region, and a p-side top cladding region over the separate confinement heterostructure active layer.

The p-side top cladding region has a ridge, which extends on a stripe-shape region, which defines the optical waveguide region. The p-side top cladding region has a three-layered structure, which comprises first to third p-cladding layers. The first p-cladding layer has a low refractive index and extends directly in contact with an entire region of a top surface of the separate confinement hctero-structure active layer. The second p-cladding layer has a high refractive index and extends directly on a selected stripe-shaped region of a top surface of the first p-cladding layer. The third p-cladding layer has a low refractive index and extends directly on a top surface of the second p-cladding layer. Laminations of the second and third p-cladding layers form the ridge, which has the stripe-shaped region, which further defines the optical waveguide region.

The n-side bottom cladding region also has a three-layered structure, which comprises first to third n-cladding layers. The first n-cladding layer has a low refractive index and extends directly in contact with an entire region of a bottom surface of the separate confinement hetero-structure active layer. The second n-cladding layer has a high refractive index and extends directly in contact with an entire region of a bottom surface of the first n-cladding layer. The third n-cladding layer has a low refractive index and extends directly in contact with an entire region of a bottom surface of the second n-cladding layer and also directly in contact with an entire region of a top surface of the substrate.

The second p-claddinig layer having the high refractive index serves as a p-side optical confinement layer. The second n-cladding layer having the high refractive index serves as an n-side optical confinement layer The separate confinement hetero-structure active layer serves as a primary optical confinement layer. In the p-side region, the p-side optical confinement layer selectively extends on the stripe-shaped region, which defines the optical waveguide region. In the n-side region, the n-side optical confinement layer entirely extends not only inside of the optical wavegluide region but also outside thereof.

The first p-cladding layer and the first n-cladding layer may have the same thickness and the same refractive index as each other, The second p-cladding layer and the second n-cladding layer may have the same thickness and the same refractive index as each other.

Inside the optical waveguide region, the refractive index profile is symmetrical with reference to the separate confinement hetero-structure active layer in a thickness direction vertical to the interfaces of the layers. Inside the optical waveguide region, a light intensity profile is symmetrical with reference to the separate confinement hetero-structure active layer in the thickness direction. The light intensity is highest in the separate confinement hetero-structure active layer, and next higher in the p-side and n-side optical confinement layers, which comprise the second p-cladding layer and the second n-cladding layer. The light intensity profile has a highest or primary peak in the separate confinement hetero-structure active layer. The light intensity profile has valleys in the first p-cladding and n-cladding layers of the lower refractive index. The light intensity profile has secondary peaks in the p-side and n-side optical confinement layers of the higher refractive index, which comprise the second p-cladding layer and the second n-cladding layer. The secondary peaks are separated by the valleys from the highest or primary peak.

Outside the optical waveguide region, the p-side optical confinement layer is absent and the n-side optical confinement layer is present. Namely, outside the optical waveguide region, the refractive index profile is asymmetrical with reference to the separate confinement hetero-structure active layer in the thickness direction. The light intensity is highest in the n-side optical confinement layer or the second n-cladding layer, and next higher in the separate confinement hetero-structure active layer. The light intensity profile has a highest or primary peak in the n-side optical confinement layer or the second n-cladding layer. The light intensity profile has valleys in the first n-cladding layer of the lower refractive index. The light intensity profile has secondary peaks in the separate confinement hetero-structure active layer. In the p-side, the light intensity profile has no peak and a simply rapid drop. Outside the optical waveguide region, the peak of the light intensity profile is shifted toward the n-side because any optical confinement structure is absent.

The n-side optical confinement cladding layer is present not only inside of the optical waveguide region but also outside thereof. The p-side optical confinement cladding layer is selectively present only on the inside of the optical waveguide region but absent the outside of the optical waveguide region. The refractive index profile is quite different between the inside and outside of the optical waveguide region. Further, the light intensity profile is also quite different between the inside and outside of the optical waveguide region. Inside the optical waveguide region, the active layer has the primary or highest peak of the light intensity profile. Outside the optical waveguide region, the active layer has the secondary peak of the light intensity profile. The active layer has the higher light intensity inside the optical waveguide region and the lower light intensity outside the optical waveguide region. The active layer has a small or reduced gain outside the optical waveguide region, and has a large or increased gain inside the optical waveguide region. Generation of the kink is suppressed.

The above asymmetrical cladding layer structure controls the lateral transverse mode in the active layer, whereby the large mode gain difference Δ_{gain} can be obtained.

As described above, in order to obtain a large difference in light intensity between the inside and outside of the optical waveguide region, the above asymmetrical cladding layer structure is effective, This increases the freedom in design of the optical intensity profile in the active layer, and controls the lateral transverse mode in the active layer, whereby the large mode gain difference Δ_{gain} can be obtained.

An available method of analyzing both Δ_{gain} and Γ will subsequently be described, wherein Δ_{gain} is the gain difference between the zero-order fundamental mode and the one-order high-order mode in the lateral transverse mode, and Γ is the optical confinement rate of the active layer in the optical waveguide region in the zero-order fundamental mode.

The analysis of Δ_{gain} may be made by using the following rate equations (1), (2), (3) and (4) in consideration of non-radiative recombination, induced emission, carrier diffusion, and transverse leak current.

$$\begin{matrix}\frac{J ( x )}{qd} + D \frac{{\partial }^{2} N ( x )}{\partial {x}^{2}} = R [ N ( x ) ] + g [ N ( x ) ] P ( x ) & ( 1 ) \\ J ( x ) = \{ \begin{matrix}{J}_{e} & ( \vert x \vert < W / 2 ) \\ \frac{{J}_{e}}{{( 1 + \frac{\vert x \vert - W / 2}{L} )}^{2}} & ( \vert x \vert \geq W / 2 )\end{matrix} & ( 2 )\end{matrix}$$

where “J” is the injection current density taking the transverse leak current into account, “q” is the unit charge of electron, “d” is the thickness of active layer, “D” is the diffusion coefficient, “N” is the carrier density, “P(x)” is the light intensity distribution, “Je” is the injection current density on the stripe-shaped region, “L” is a current broadening in the lateral direction, “W” is the width of the stripe-shaped region, R[N(x)] is the carrier life-time represented by the carrier density distribution function N(x), and “g” is the optical gain represented by the carrier density distribution function N(x).

R(N)=/τ+BN² . . . (3)

g(N)=Γνζln(N/N₀ . . . (4)

where “τ” is the time constant for the non-radiative recombination, “B” is the carrier recombination by spontaneous emission, “Γ” is the optical confinement rate of the active layer, “ν” is the group velocity of light, “ζ” is the differential gain, and “N₀” is the population inversion carrier density. The gain “g(N)” is represented by taking into account the effect of saturation upon a high current injection.

From the above equations, the distribution of the carrier density can be obtained. Based on this result, a gain/loss distribution is added to the refractive index distribution of the optical waveguide. A mode analysis to the optical waveguide is made to calculate a gain difference between the fundamental mode and the high-order mode. The gain difference varies depending on operational conditions such as injection current. It is, however, assumed that the optical output is 100 mW. The above individual parameters are D=10(cm²/s), τ=10(ns), B=1E-10 (cm³/s), ζ=1500 (cm-¹), NO=E18(cm-³).

For the optical mode analysis, the approximately calculation method such as equivalent refractive index method is not so highly accurate analysis method. A two-dimensional mode analysis method such as finite element method or finite difference method is preferable for the highly accurate optical mode analysis. In this example, the finite difference method is used as the two-dimensional mode analysis method.

If the optical waveguide is placed in a cut-off condition, under which the high-order mode is not generated, it is possible that the result of the optical mode analysis is not well converged. In this case, it may be possible to converge the result of the optical mode analysis by an available method such as widening the width of the stripe-shaped region. A highly accurate evaluation of the mode gain difference is difficult, but a relative evaluation between the modified structures for convergence of the solution is usable.

If there are plural active layers such as multiple quantum wells, the optical confinement rate may be calculated by simply summing individual optical confinement rates of individual active layers such as quantum wells.

Consequently, it is important for the present invention that Δ_{gain}/ Γ is high to obtain a high kink output.

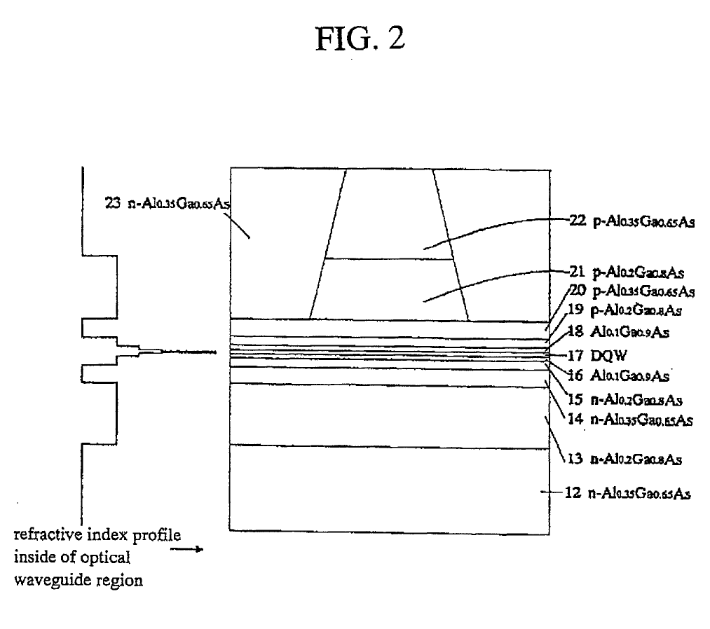

A first embodiment according to the present invention will be described in detail with reference to FIG. 2. The semiconductor laser device has an n-GaAs substrate not illustrated, an n-cladding region, a self confinement hetero-structure active layer, a p-cladding region, and current blocking layers. The n-cladding region is provided over the n-GaAs substrate. The n-cladding region is in contact directly with an entire region of a top surface of the n-GaAs substrate. The self confinement hetero-structure active layer is provided over the n-cladding region. The self confinement hetero-structure active layer is in contact directly with an entire region of a top surface of the n-cladding region. The p-cladding region is provided over the self confinement hetero-structure active layer. The p-cladding region is in contact directly with an entire region of a top surface of the self confinement hetero-structure active layer. The p-cladding region further has a mesa-structure which extends on a stripe-shaped region. A width of the mesa-structure is 2.8 micrometers. The current blocking layers are provided in contact directly with both sloped side faces of the mesa-structure and with planarized surfaces outside the stripe-shaped region.

The n-cladding region has the following multi-layered structure, which varies refractive index in a thickness direction. An n-Al_{0.35}G_{0.65}As cladding layer 12 having a thickness of 1000 nanometers is provided in contact directly with an entire region of the top surface of the non-illustrated n-GaAs substrate. An n-Al_{0.2}Ga_{0.8}As cladding layer 13 having a thickness of 700 nanometers is provided in contact directly with an entire region of the top surface of the n-Al_{0.35}Ga_{0.65}As cladding layer 12. An n-Al_{0.35}Ga_{0.65}As cladding layer 14 having a thickness of 200 nanometers is provided in contact directly with an entire region of the top surface of the n-Al_{0.2}Ga_{0.8}As cladding layer 13.

The n-Al_{0.2}Ga_{0.8}As cladding layer 13 is sandwiched between the n-AI_{0.35}Ga_{0.65}As cladding layers 12 and 14, wherein the n-Al_{0.2}Ga_{0.8}As cladding layer 13 is higher in refractive index than the n-Al_{0.35}Ga_{0.65}As cladding layers 12 and 14.

The self confinement hetero-structure active layer has the following multi-layered structure, which varies refractive index in a thickness direction. An n-Al_{0.2}Ga_{0.8}As layer 15 having a thickness of 100 nanometers is provided in contact directly with an entire region of the top surface of the n-cladding region or the n-Al_{0.35}(Ga_{0.65}As cladding layer 14. An Al_{0.1}Ga_{0.9}As layer 16 having a thickness of 40 nanometers is provided in contact directly with an entire region of the top surface of the n-Al_{0.2}Ga_{0.8}As layer 15. A double quantum well active layer 17 of InGaAs quantum well layer having a thickness of 4.1 nanometers and GaAs potential barrier layer having a thickness of 5 nanometers is provided in contact directly with an entire region of the top surface of the Al_{0.1}Ga_{0.9}As layer 16. An Al_{0.1}Ga_{0.9}As layer 18 having a thickness of 40 nanometers is provided in contact directly with an entire region of the top surface of the double quantum well active layer 17. A p-Al_{0.2}Ga_{0.8}gAs layer 19 having a thickness of 100 nanometers is provided in contact directly with an entire region of the top surface of the Al_{0.1}Ga_{0.9}As layer 18.

The double quantum well active layer 17 is sandwiched between the Al_{0.1}Ga_{0.9}As layers 16 and 18, wherein the double quantum well active layer 17 is higher in refractive index than the Al_{0.1}Ga_{0.9}As layers 16 and 18. The laminations of the layers 16, 17 and 18 are disposed between the n-Al_{0.2}Ga_{0.8}As layer 15 and the p-Alhd 0.2Ga_{0.8}As layer 19, wherein the Al_{0.1}Ga_{0.9}As layers 16 and 18 are higher in refractive index than the n-Al_{0.2}Ga_{0.8}As layer 15 and the p-Al_{0.2}Ga_{0.8}As layer 19. The double quantum well active layer 17 is highest in refractive index. The Al_{0.1}Ga_{0.9}As layers 16 and 18 are second higher in refractive index. The n-Al_{0.2}Ga_{0.8}As layer 15 and the p-Al_{0.2}Ga_{0.8}As layer 19 are lower in refractive index but are the same level as the n-Al_{0.2}Ga_{0.8}As cladding layer 13 in the n-cladding region, wherein the n-Al_{0.2}Ga_{0.8}As cladding layer 13 is highest in refractive index in the n-cladding region.

The p-cladding region has the following multi-layered structure, which varies refractive index in a thickness direction, A p-Al_{0.35}Ga_{0.65}As cladding layer 20 having a thickness of 200 nanometers is provided in contact directly with an entire region of the top surface of the self confinement hetero-structure active layer or the p-Al_{0.2}Ga_{0.8}As layer 19. A mesa-structure is selectively provided on a stripe-shaped region of a top surface of the p-Al_{0.35}Ga_{0.65}As cladding layer 20. The stripe-shaped region defines the optical waveguide region. The mesa-structure comprises the following double-layered structure. A p-Al_{0.2}Ga_{0.8}As cladding layer 21 having a thickness of 700 nanometers is provided in contact directly with the stripe-shaped region of the top surface of the p-Al_{0.35}Ga_{0.65}As cladding layer 20. The p-Al_{0.2}Ga_{0.8}As cladding layer 21 has a ridge-shape. A p-Al_{0.35}Ga_{0.65}As cladding layer 22 having a thickness of 1000 nanometers is provided in contact directly with a top surface of the p-Al_{0.2}Ga_{0.8}As cladding layer 21. The p-Al_{0.35}Ga_{0.65}As cladding layer 22 has a ridge-shape.

Further, n-Al_{0.35}Ga_{0.65}As current blocking layers 23 are provided in contact directly with opposite side regions of the top surface of the p-Al_{0.35}Ga_{0.65}As cladding layer 20 and also in contact directly with sloped side faces of the mesa-structure, wherein the opposite side regions extend in opposite sides of the stripe-shaped region.

The p-Al_{0.2}Ga_{0.8}As cladding layer 21 is sandwiched between the p-Al_{0.35}Ga₆₅As cladding layers 20 and 22, wherein the p-Al_{0.2}Ga_{0.8}As cladding layer 21 is higher in refractive index than the p-AI_{0.35}Ga_{0.65}As cladding layers 20 and 22.

The refractive index profile in the optical waveguide region defined by the stripe-shaped region is symmetrical in the thickness direction as described below. The p-Al_{0.35}Ga_{0.65}As cladding layer 20 in the p-cladding region is identical in thickness and refractive index with the n-Al_{0.35}Ga_{0.65}As cladding layer 14 in the n-cladding region. The p-Al_{0.2}Ga_{0.8}As cladding layer 21 in the p-cladding region is identical in thickness and refractive index with the n-Al_{0.2}Ga_{0.8}As cladding layer 13 in the n-cladding region. The p-Al_{0.35}Ga_{0.65}As cladding layer 22 in the p-cladding region is identical in thickness and refractive index with the n-Al_{0.35}Ga_{0.65}As cladding layer 12 in the n-cladding region. The n-Al_{0.2}Ga_{0.8}As layer 15 and the p-Al_{0.2}Ga_{0.8}As layer 19 of the self-confinement hetero-structure active layer are identical with each other in thickness and refractive index, The Al_{0.1}Ga_{0.9}As layers 16 and 18 of the self-confinement hetero-structure active layer are identical with each other in thickness and refractive index.

The double quantum well active layer 17 is highest in refractive index. The Al_{0.1}Ga_{0.9}As layers 16 and 18 are second in refractive index.

The n-Al_{0.2}Ga_{0.8}As layer 15 and the p-Al_{0.2}Ga_{0.8}As layer 19 as well as the n-Al_{0.2}Ga_{0.8}As cladding layer 13 in the n-cladding region and the p-Al_{0.2}Ga_{0.8}As cladding layer 21 in the p-cladding region are third level in refractive index. The n-Al_{0.35}Ga_{0.65}As cladding layers 14 and 12 in the n-cladding region and the p-Al_{0.35}Ga_{0.65}As cladding layers 20 and 22 in the p-cladding region are lowest in refractive index.

Accordingly, inside the optical waveguide region defined by the stripe-shaped region, the refractive index profile is symmetrical with reference to the double quantum well active layer 17 in the thickness direction. Outside the optical waveguide region, however, the refractive index profile is asymmetrical with reference to the double quantum well active layer 17 in the thickness direction. As described above, the light intensity depends upon the refractive index. The light intensity profile also depends upon the refractive index profile.

Inside the optical waveguide region, a primary optical confinement is obtained in the self confinement hetero-structure active layer, which is highest in refractive index, and a secondary optical confinement is obtained both in the n-Al_{0.2}Ga_{0.8}As cladding layer 13, which is higher in refractive index in the n-cladding region as well as in the p-Al_{0.2}Ga_{0.8}As cladding layer 21, which is higher in refractive index in the p-cladding region. Therefore, inside the optical waveguide region, the light intensity profile is symmetrical with reference to the double quantum well active layer 17 in the thickness direction.

Outside the optical wavegLLide region, the primary optical confinement is obtained only in the n-Al_{0.2}Ga_{0.8}As cladding layer 13 in the n-cladding region, and the secondary optical confinement is obtained in the self confinement hetero-structure active layer Therefore, outside the optical waveguide region, the light intensity profile is asymmetrical with reference to the double quantum well active layer 17 in the thickness direction.

The semiconductor laser device has a buried ridge-shaped optical waveguide for emitting a laser beam of a wavelength at 0.98 micrometers. The mode gain difference and the optical confinement rate are calculated. Δ_{gain}/Γ is 87.60[cm-⁻¹/%] which satisfies the requirement thatΔ_{gain}/Γ is at least 85 [cm⁻¹/%]. The double quantum well active layer 17 has two quantum wells, cach of which has an optical confinement rate Γ at 0.394% in the fundamental mode. If a cavity length is 890 micrometers, then an average kink output is 285 mW, wherein the width of the stripe-shaped region is 2.8 micrometers.

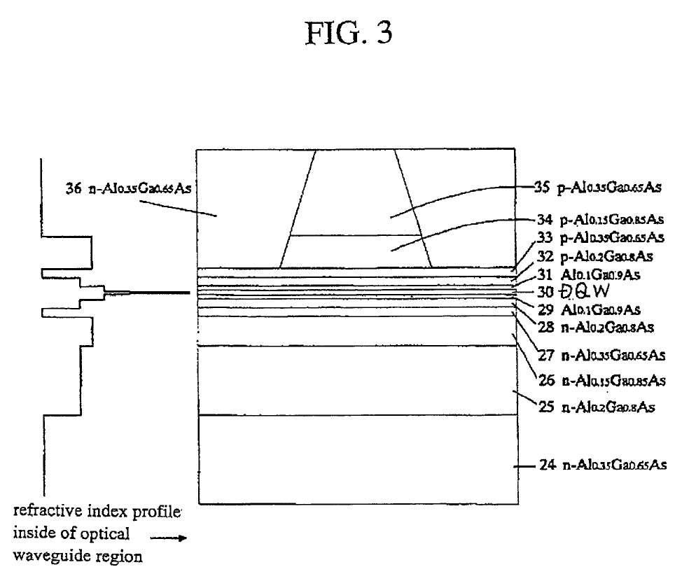

A second embodiment according to the present invention will be described in detail with reference to FIG. 3. A main difference of this second embodiment from the first embodiment is as follows. The refractive index profile inside the optical waveguide region is asymmetrical with reference to the self confinement hetero-structure active layer in the thickness direction, wherein inside the optical waveguide region, the n-cladding region is higher in average refractive index than the p-cladding region having the mesa-structure. Namely, the light intensity profile inside the optical waveguide region is asymmetrical with reference to the self confinement hetero-structure active layer in the thickness direction, wherein inside the optical waveguide region, the n-cladding region is higher in average optical intensity than the p-cladding region having the mesa-structure.

A subordinate difference of this second embodiment from the first embodiment is as follows. The n-cladding region comprises a four-layered structure which includes not only a main optical confinement layer but also a subordinate optical confinement layer. The p-cladding region has the same structure as in the first embodiment. Namely, the p-cladding region has the mesa-structure and comprises the three-layered structure.

Another subordinate difference of this second embodiment from the first embodiment is as follows. The self confinement hetero-structure active layer includes a multiple quantum well structure in place of the above double quantum well structure.

The semiconductor laser device has an n-GaAs substrate not illustrated, an n-cladding region, a self confinement hetero-structure active layer including a multiple quantum well structure, a p-cladding region, and current blocking layers. The n-cladding region is provided over the n-GaAs substrate. The n-cladding region is in contact directly with an entire region of a top surface of the n-GaAs substrate. The self confinement hetero-structure active layer is provided over the n-cladding region, The self confinement hetero-structure active layer is in contact directly with an entire region of a top surface of the n-cladding region. The p-cladding region is provided over the self confinement hetero-structure active layer. The p-cladding region is in contact directly with an entire region of a top surface of the self confinement hetero-structure active layer. The p-cladding region further has a mesa-structure which extends on a stripe-shaped region. A width of the mesa-structure is 2.8 micrometers. The current blocking layers are provided in contact directly with both sloped side faces of the mesa-structure and with planarized surfaces outside the stripe-shaped region.

The n-cladding region. has the following multi-layered structure, which varies refractive index in a thickness direction. An n-Al_{0.35}Ga_{0.65}As cladding layer 24 having a thickness of 1000 nanometers is provided in contact directly with an entire region of the top surface of the non-illustrated n-GaAs substrate. An n-Al_{0.2}Ga_{0.8}As cladding layer 25 having a thickness of 800 nanometers is provided in contact directly with an entire region of the top surface of the n-Al_{0.35}Ga_{0.65}As cladding layer 24. An n-Al_{0.15}Ga_{0.85}As cladding layer 26 having a thickness of 350 nanometers is provided in contact directly with an entire region of the top surface of the n-Al_{0.2}Ga_{0.8}As cladding layer 25. An n-Al_{0.35}Ga_{0.65}As cladding layer 27 having a thickness of 100 nanometers is provided in contact directly with an entire region of the top surface of the n-Al_{0.15}Ga_{0.85}As cladding layer 26.

The laminations of the n-Al_{0.2}Ga_{0.8}As cladding layer 25 and the n-Al_{0.15}Ga_{0.85}As cladding layer 26 are sandwiched between the n-Al_{0.35}Ga_{0.65}As cladding layers 24 and 27, wherein the n-Al_{0.15}Ga0.85As cladding layer 26 and the n-Al_{0.2}Ga_{0.8}As cladding layer 25 are higher in refractive index than the n-Al_{0.35}Ga_{0.65}As cladding layers 24 and 27. The n-Al_{0.15}Ga_{0.85}As cladding layer 26 is higher in refractive index than the n-Al_{0.2}Ga_{0.8}As cladding layer 25.

The self confinement hetero-structure active layer has the following multi-layered structure, which varies refractive index in a thickness direction. An n-Al_{0.2}Ga_{0.8}As layer 28 having a thickness of 100 nanometers is provided in contact directly with an entire region of the top surface of the n-cladding region or the n-Al_{0.35}Ga_{0.65}As cladding layer 27. An Al_{0.1}Ga_{0.9}As layer 29 having a thickness of 60 nanometers is provided in contact directly with an entire region of the top surface of the n-Al_{0.2}Ga_{0.8}As layer 28. A multiple quantum well active layer 30 of InGaAs quantum well layer having a thickness of 4.1 nanometers and GaAs potential barrier layer having a thickness of 5 nanometers is provided in contact directly with an entire region of the top surface of the Al_{0.1}Ga_{0.9}As layer 29. An Al_{0.1}Ga_{0.9}As layer 31 having a thickness of 60 nanometers is provided in contact directly with an entire region of the top surface of the multiple quantum well active layer 30. A p-Al_{0.2}Ga_{0.8}As layer 32 having a thickness of 100 nanometers is provided in contact directly with an entire region of the top surface of the Al_{0.1}Ga_{0.9}As layer 31.

The multiple quantum well active layer 30 is sandwiched between the Al_{0.1}Ga_{0.9}As layers 29 and 31, wherein the multiple quantum well active layer 30 is higher in refractive index than the Al_{0.1}Ga_{0.9}As layers 29 and 31. The laminations of the layers 29, 30 and 31 are disposed between the n-Al_{0.2}Ga_{0.8}As layer 28 and the p-Al_{0.2}Ga_{0.8}As layer 32, wherein the Al_{0.1}Ga_{0.9}As layers 29 and 31 arc higher in refractive index than the n-Al_{0.2}Ga_{0.8}As layer 28 and the p-Al_{0.2}Ga_{0.8}As layer 32. The multiple quantum well active layer 30 is highest in refractive index. The Al_{0.1}Ga_{0.9}As layers 29 and 31 are second higher in refractive index. The n-Al_{0.2}Ga_{0.8}As layer 28 and the p-Al_{0.2}Ga_{0.8}As layer 32 are lower in refractive index but are the same level as the n-Al_{0.2}Ga_{0.8}As cladding layer 25 in the n-cladding region, wherein the n-Al_{0.2}Ga_{0.8}As cladding layer 25 is second highest in refractive index in the n-cladding region.

The p-cladding region has the following multi-layered structure, which varies refractive index in a thickness direction. A p-Al_{0.3.5}Ga_{0.65}As cladding layer 33 having a thickness of 100 nanometers is provided in contact directly with an entire region of the top surface of the self confinement hetero-structure active layer or the p-Al_{0.2}Ga_{0.8}As layer 32. A mesa-structure is selectively provided on a stripe-shaped region of a top surface of the p-Al_{0.35}Ga_{0.65}As cladding layer 33. The stripe-shaped region defines the optical waveguide region. The mesa-structure comprises the following double-layered structure. A p-Al_{0.15}Ga_{0.85}As cladding layer 34 having a thickness of 375 nanometers is provided in contact directly with the stripe-shaped region of the top surface of the p-Al_{0.35}Ga_{0.65}As cladding layer 33. The p-Al_{0.15}Ga_{0.85}As cladding layer 34 has a ridge-shape. A p-Al_{0.35}Ga_{0.65}As cladding layer 35 having a thickness of 1000 nanometers is provided in contact directly with a top surface of the p-Al_{0.15}Ga_{0.85}As cladding layer 34. The p-Al_{0.35}Ga_{0.65}As cladding layer 35 has a ridge-shape.

Further, n-AI_{0.35}Ga_{0.65}As current blocking layers 36 are provided in contact directly with opposite side regions of the top surface of the p-Al_{0.35}Ga_{0.65}As cladding layer 33 and also in contact directly with sloped side faces of the mesa-structure, wherein the opposite side regions extend in opposite sides of the stripe-shaped region.

The p-Al_{0.15}Ga_{0.85}As cladding layer 34 is sandwiched between the p-Al_{0.35}Ga_{0.85}As cladding layers 33 and 35, wherein the p-Al_{0.15}Ga_{0.85}As cladding layer 34 is higher in refractive index than the p-Al_{0.35}Ga_{0.65}As cladding layers 33 and 35.

The refractive index profile in the optical waveguide region defined by the stripe-shaped region is symmetrical in the thickness direction as described below. The p-Al_{0.35}Ga_{0.65}As cladding layer 33 in the p-cladding region is identical in thickness and refractive index with the n-Al_{0.35}Ga_{0.65}As cladding layer 27 in the n-cladding region. The p-Al_{0.15}Ga_{0.85}As cladding layer 34 in the p-cladding region is identical in refractive index with the n-Al_{0.15}Ga_{0.65}As cladding layer 26 in the n-cladding region. The p-Al_{0.35}Ga_{0.65}As cladding layer 35 in the p-cladding region is identical in thickness and refractive index with the n-Al_{0.35}Ga_{0.65}As cladding layer 24 in the n-cladding region. The n-Al_{0.2}Ga_{0.8}As layer 28 and the p-Al_{0.2}Ga_{0.8}As layer 32 of the self-confinement hetero-structure active layer are identical with each other in thickness and refractive index. The Al_{0.1}Ga_{0.9}As layers 29 and 31 of the self-confinement hetero-structure active layer are identical with each other in thickness and refractive index. In the p-cladding region, the n-Al_{0.2}Ga_{0.8}As layer 25 has no corresponding layer in the n-cladding region. Namely, the presence of the n-Al_{0.2}Ga_{0.8}As layer 25 in the p-cladding region makes an asymmetrical refractive index profile, and causes that the n-cladding region is higher in averaged refractive index than the p-cladding layer.

The multiple quantum well active layer 30 is highest in refractive index. The Al_{0.1}Ga_{0.9}As layers 29 and 31 are second in refractive index. The n-Al_{0.2}Ga_{0.8}As layer 28 and the p-AI_{0.2}Ga_{0.8}As layer 32 as well as the n-Al_{0.2}Ga_{0.8}As cladding layer 25 in the n-cladding region and the p-Al_{0.2}Ga_{0.8}As cladding layer 34 in the p-cladding region are fourth level in refractive index, because the n-Al_{0.15}Ga_{0.85}As cladding layer 26 in the n-cladding region and the p-Al_{0.15}Ga_{0.85}As cladding layer 34 in the p-cladding region are third level in refractive index. The n-Al_{0.35}Ga_{0.65}As cladding layers 27 and 24 in the n-cladding region and the p-Al_{0.35}Ga_{0.65}As cladding layers 33 and 35 in the p-cladding region are lowest in refractive index. Accordingly, inside the optical waveguide region defined by the stripe-shaped region, the refractive index profile is asymmetrical with reference to the multiple quantum well active layer 30 in the thickness direction. Outside the optical waveguide region, the refractive index profile is also asymmetrical with reference to the multiple quantum well active layer 30 in the thickness direction. The presence of the n-Al_{0.2}Ga_{0.8}As layer 25 in the p-cladding region makes the asymmetrical refractive index profile, wherein the n-cladding region is higher in averaged refractive index than the p-cladding layer. As described above, the light intensity depends upon the refractive index. The light intensity profile also depends upon the refractive index profile.

Inside the optical waveguide region, a primary optical confinement is obtained in the self confinement hetero-structure active layer, which is highest in refractive index. A secondary optical confinement is obtained both in the n-Al_{0.15}Ga_{0.85}As cladding layer 26 in the n-cladding region and in the p-Al_{0.15}Ga_{0.85}As cladding layer 34 in the p-cladding region. A ternary optical confinement is obtained in the n-Al_{0.2}Ga_{0.8}As cladding layer 25, which is higher in refractive index in the n-cladding region as well as in the n-Al_{0.2}Ga_{0.8}As layer 28 and the p-Al_{0.2}Ga_{0.8}As layer 32. Therefore, inside the optical waveguide region, the light intensity profile is asymmetrical with reference to the multiple quantum well active layer 30 in the thickness direction, wherein the n-cladding region is higher in averaged light intensity than the p-cladding layer.

Outside the optical waveguide region, the primary optical confinement is obtained only in the n-Al_{0.2}Ga_{0.8}As cladding layer 25 in the n-cladding region, and the secondary optical confinement is obtained in the self confinement hetero-structure active layer. Therefore, outside the optical waveguide region, the light intensity profile is asymmetrical with reference to the multiple quantum well active layer 30 in the thickness direction.

The presence of the n-Al_{0.2}Ga_{0.8}As cladding layer 25 in the n-cladding region increases a difference in the optical confinement rate of the active layer between the optical waveguide region and the outside regions, resulting in an increased mode gain difference Δ _{gain-}

The semiconductor laser device has a buried ridge-shaped optical waveguide for omitting a laser beam of a wavelength at 0.98 micrometers. The mode gain difference and the optical confinement rate are calculated. Δ_{gain}//Γ is 98.68[cm−1/%] which satisfies the requirement that Δ_{gain}/Γ is at least 85 [cm−1/%]. The multiple quantum well active layer 30 has two quantum wells, each of which has an optical confinement rate Γ at 0.385% in the fundamental mode. If a cavity length is 890 micrometers, then an average kink output is 328 mW, wherein the width of the stripe-shaped region is 2.8 micrometers. If a cavity length is 1200 micrometers, then an average kink output is 346 mW, wherein the width of the stripe-shaped region is 2.8 micrometers.

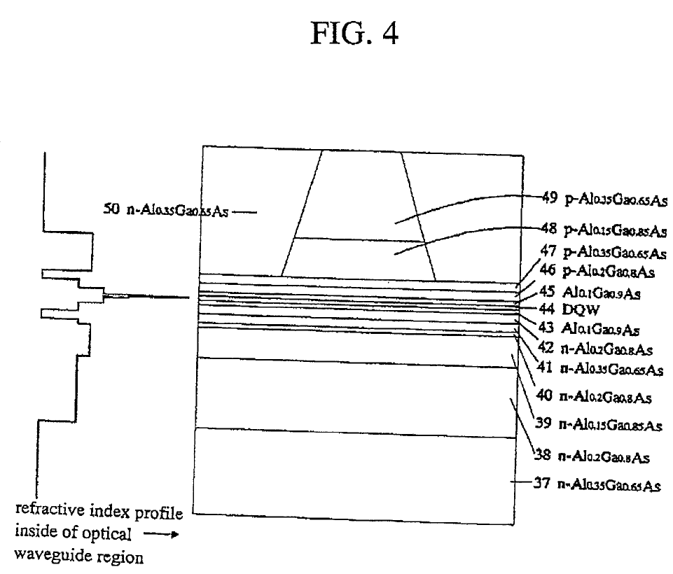

A third embodiment according to the present invention will be described in detail with reference to FIG. 4. A main difference of this third embodiment from the second embodiment is as follows. The increase of the optical confmement rate in the n-cladding region increases the difference in the optical confinement rate in the active layer between the optical waveguide region and the outside regions, resulting in the increased mode gain difference. If, however, the optical confinement rate in the n-cladding region is excessively increased, then the influence of the optical confinement structure by the p-cladding region to the n-cladding region is increased. As a result, the light intensity profile in the n-cladding region is spread over the inside and outside of the optical waveguide region defined by the stripe-shaped region. This spreading causes that light intensity profile in the active layer is spread over the inside and outside of the optical waveguide region defined by the stripe-shaped region, resulting in influence of the gain in the peripheral portion of the stripe-shaped region. In this embodiment, the refractive index profile of the n-cladding region is adjusted to avoid the excess spread of the light intensity profile over not only inside but also outside the optical waveguide region defined in the stripe-shaped region.

The semiconductor laser device has an n-GaAs substrate not illustrated, an n-cladding region, a self confinement hetero-structure active layer including a multiple quantum well structure, a p-cladding region, and current blocking layers. The n-cladding region is provided over the n-GaAs substrate. The n-cladding region is in contact directly with an entire region of a top surface of the n-GaAs substrate. The self confinement hetero-structure active layer is provided over the n-cladding region. The self confinement hetero-structure active layer is in contact directly with an entire region of a top surface of the n-cladding region. The p-cladding region is provided over the self confinement hetero-structure active layer. The p-cladding region is in contact directly with an entire region of a top surface of the self confinement hetero-structure active layer. The p-cladding region further has a mesa-structure which extends on a stripe-shaped region, A width of the mesa-structure is 42 micrometers. The current blocking layers are provided in contact directly with both sloped side faces of the mesa-structure and with planarized surfaces outside the stripe-shaped region.

The n-cladding region has the following multi-layered structure, which varies refractive index in a thickness direction. An n-Al_{0.35}Ga_{0.65}As cladding layer 37 having a thickness of 1000 nanometers is provided in contact directly with an entire region of the top surface of the non-illustrated n-GaAs substrate. An n-Al_{0.2}Ga_{0.8}As cladding layer 38 having a thickness of 800 nanometers is provided in contact directly with an entire region of the top surface of the n-Al_{0.35}Ga_{0.65}As cladding layer 37. An n-Al_{0.15}Ga_{0.85}As cladding layer 39 having a thickness of 375 nanometers is provided in contact directly with an entire region of the top surface of the n-Al_{0.2}Ga_{0.8}As cladding layer 38. An n-Al_{0.2}Ga_{0.8}As cladding layer 40 having a thickness of 50 nanomneters is provided in contact directly with an entire region of the top surface of the n-Al_{0.15}Ga_{0.85}As cladding layer 39. An n-Al_{0.35}Ga_{0.65}As cladding layer 41, having a thickness of 100 nanometers is provided in contact directly with an entire region of the top surface of the n-Al_{0.2}Ga_{0.8}As cladding layer 40.

The n-Al_{0.15}Ga_{0.85}As cladding layer 39 is sandwiched between the n-Al_{0.2}Ga_{0.8}As cladding layers 38 and 40, wherein the n-Al_{0.15}Ga_{0.85}As cladding layer 39 is higher in refractive index than. The laminations of the layers 38, 39 and 40 are disposed between the n-Al_{0.35}ga_{0.65}As cladding layers 37 and 41, wherein the n-Al_{0.15}Ga_{0.85}As cladding layer 39 and the n-Al_{0.2}Ga_{0.8}As cladding layers 38 and 40 are higher in refractive index than the n-Al_{0.35}Ga_{0.65}As cladding layers 37 and 41.

The presence of the n-AI_{0.2}Ga_{0.8}As cladding layer 40 avoids the excessive optical confinement in the n-cladding region. As a result, the light intensity profile in the n-cladding region does not any excessive spread over the inside and outside of the optical waveguide region defined by the stripe-shaped region. This non-excessive spreading does not cause that light intensity profile in the active layer is spread over the inside and outside of the optical waveguide region defined by the stripe-shaped region, resulting in a reduced influence of the gain in the peripheral portion of the stripe-shaped region In this embodiment, the presence of the n-Al_{0.2}Ga_{0.8}As cladding layer 40 avoids the excess spread of the light intensity profile over not only inside but also outside the optical waveguide region defined in the stripe-shaped region.

The self confinement hetero-structure active layer has the following multi-layered structure, which varies refractive index in a thickness direction. An n-Al_{0.2}Ga_{0.8}As layer 42 having a thickness of 100 nanometers is provided in contact directly with an entire region of the top surface of the n-cladding region or the n-Al_{0.35}Ga_{0.65}As cladding layer 41. An Al_{0.1}Ga_{0.9}As layer 43 having a thickness of 65 nanometers is provided in contact directly with an entire region of the top surface of the n-Al_{0.2}Ga_{0.8}As layer 42. A multiple quantum well active layer 44 of InGaAs quantum well layer having a thickness of 4.1 nanometers and GaAs potential barrier layer having a thickness of 5 nanotneters is provided in contact directly with an entire region of the top surface of the Al_{0.1}Ga_{0.9}As layer 43. An Al_{0.1}Ga_{0.9}As layer 45 having a thickness of 65 nanometers is provided in contact directly with an entire region of the top surface of the multiple quantum well active layer 44. A p-Al_{0.2}Ga_{0.8}As layer 46 having a thickness of 100 nanometers is provided in contact directly with an entire region of the top surface of the Al_{0.1}Ga_{0.9}As layer 45.

The multiple quantum well active layer 44 is sandwiched between the Al_{0.1}Ga_{0.9}As layers 43 and 45, wherein the multiple quantum well active layer 44 is higher in refractive index than the Al_{0.1}Ga₀₉As layers 43 and 45. The laminations of the layers 43, 44 and 45 are disposed between the n-Al_{0.2}Ga_{0.8}As layer 42 and the p-Al_{0.2}Ga_{0.8}As layer 46, wherein the Al_{0.1}Ga_{0.9}As layers 43 and 45 are higher in refractive index than the n-Al_{0.2}Ga_{0.8}As layer 42 and the p-Al_{0.2}Ga_{0.8}As layer 46. The multiple quantum well active layer 44 is highest in refractive index The Al_{0.1}Ga_{0.9}As layers 43 and 45 are second higher in refractive index. The n-Al_{0.2}Ga_{0.8}As layer 42 and the p-Al_{0.2}Ga_{0.8}As layer 46 are lower in refractive index but are the same level as the n-Al_{0.2}Ga_{0.8}As cladding layers 38 and 40 in the n-cladding region, wherein the n-Al_{0.2}Ga_{0.8}As cladding layers 38 and 40 are second highest in refractive index in the n-cladding region.

The p-cladding region has the following mnulti-layered structure, which varies refractive index in a thickness direction. A p-Al_{0.35}Ga_{0.65}As cladding layer 47 having a thickness of 100 nanometers is provided in contact directly with an entire region of the top surface of the self confinement hetero-structure active layer or the p-Al_{0.2}Ga_{0.8}As layer 46. A mesa-structure is selectively provided on a stripe-shaped region of a top surface of the p-A_{0.35}Ga_{0.65}As cladding layer 47. The stripe-shaped region defines the optical waveguide region. The mesa-structure comprises the following double-layered structure. A p-Al₀₁₅Ga_{0.85}As cladding layer 48 having a thickness of 450 nanometers is provided in contact directly with the stripe-shaped region of the top surface of the p-A1_{0.35}Ga_{0.65}As cladding layer 47. The p-Al_{0.15}Ga_{0.85}As cladding layer 48 has a ridge-shape. A p-Al_{0.35}Ga_{0.65}As cladding layer 49 having a thickness of 1000 nanometers is provided in contact directly with a top surface of the p-Al_{0.15}Ga_{0.85}As cladding layer 48. The p-Al_{0.35}Ga_{0.65}As cladding layer 49 has a ridge-shape.

Further, n-Al_{0.35}Ga_{0.65}As current blocking layers 50 are provided in contact directly with opposite side regions of the top surface of the p-Al_{0.35}Ga_{0.65}As cladding layer 47 and also in contact directly with sloped side faces of the mesa-structure, wherein the opposite side regions extend in opposite sides of the stripe-shaped region.

The p-Al_{0.15}Ga_{0.85}As cladding layer 48 is sandwiched between the p-Al_{0.35}Ga_{0.65}As cladding layers 47 and 49, wherein the p-Al_{0.15}Ga_{0.85}As cladding layer 48 is higher in refractive index than the p-Al_{0.35}Ga_{0.65}As cladding layers 47 and 49.

The refractive index profile in the optical wavegguide region defined by the stripe-shaped region is asymmetrical in the thickness S direction as described below. The p-Al_{0.35}Ga_{0.65}As cladding layer 47 in the p-cladding region is identical in thickness and refractive index with the n-Al_{0.35}Ga_{0.65}As cladding layer 41 in the n-cladding region. The p-Al_{0.15}Ga_{0.85}As cladding layer 48 in the p-cladding region is identical in refractive index with the n-Al_{0.15}Ga_{0.85}As cladding layer 39 in the n-cladding region. The p-Al_{0.35}Ga_{0.65}As cladding layer 49 in the p-cladding region is identical in thickness and refractive index with the n-Al_{0.35}Ga_{0.65}As cladding layer 37 in the n-cladding region. The n-Al_{0.2}Ga_{0.8}As layer 42 and the p-Al_{0.2}Ga_{0.8}As layer 46 of the self-confinement hetero-structure active layer are identical with each other in thickness and refractive index. The Al_{0.1}Ga_{0.9}As layers 43 and 45 of the self-confmement hetero-structure active layer are identical with each other in thickness and refractive index. In the p-cladding region, the n-Al_{0.2}Ga_{0.8}As layers 38 and 40 have no corresponding layer in the n-cladding region. Namely, the presence of the n-A_{0.2}Ga_{0.8}As layers 38 and 40 in the p-cladding region makes an asymtmetrical refractive index proflile, and causes that the n-cladding region is higher in averaged refractive index than the p-cladding layer.

The multiple quantum well active layer 44 is highest in refractive index. The Al_{0.1}Ga_{0.9}layers 43 and 45 are second in refractive index. The p-Al_{0.15}Ga_{0.85}As cladding layer 48 in the p-cladding region and the n-Al_{0.15}Ga_{0.85}As cladding layer 39 in the n-cladding region are third level in refractive index. The n-Al_{0.2}Ga_{0.8}As layer 42 and the p-Al_{0.2}Ga_{0.8}As layer 46 as well as the n-Al_{0.2}Ga_{0.8}As cladding layers 38 and 40 in the n-cladding region are fourth level in refractive index The n-Al_{0.35}Ga_{0.65}As cladding layers 41 and 37 in the n-cladding region and the p-Al_{0.35}Ga_{0.65}As cladding layers 47 and 49 in the p-cladding region are lowest in refractive index.

Accordingly, inside the optical waveguide region defined by the stripe-shaped region, the refractive index profile is asymmetrical with reference to the multiple quantum well active layer 44 in the thickness direction. Outside the optical waveguide region, the refractive index profile is also asymmetrical with reference to the multiple quantum well active layer 44 in the thickness direction. The presence of the n-Al_{0.2}Ga_{0.8}As layer 38 in the p-cladding region makes the asymmetrical refractive index profile, wherein the n-cladding region is higher in averaged refractive index than the p-cladding layer. As described above, the light intensity depends upon the refractive index. The light intensity profile also depends upon the refractive index profile,

Inside the optical waveguide region, a primary optical confinement is obtained in the self confinement hetero-structure active layer, which is highest in refractive indx. A secondary optical confinement is obtained both in the n-Al_{0.15}Ga_{0.85}As cladding layer 39 in the n-cladding region and in the p-Al_{0.15}Ga_{0.85}As cladding layer 48 in the p-cladding region. A ternary optical confinement is obtained in the n-Al_{0.2}Ga_{0.8}As cladding layers 38 and 40, which are higher in refractive index in the n-cladding region as well as in the n-Al_{0.2}Ga_{0.8}As layer 42 and the p-Al_{0.2}Ga_{0.8}As layer 46, Therefore, inside the optical waveguide region, the light intensity profile is asymmetrical with reference to the multiple quantum well active layer 44 in the thickness direction, wherein the n-cladding region is higher in averaged light intensity than the p-cladding layer.

Outside the optical waveguide region, the primary optical confinement is obtained only in the n-Al_{0.2}Ga_{0.8}As cladding layer 38 in the n-cladding region, and the secondary optical confinement is obtained in the self confinement hetero-structure active layer. Therefore, outside the aoptical waveguide region, the light intensity profile is asymmetrical with reference to the multiple quantum well active layer 44 in the thickness direction.

The presence of the n-Al_{0.2}Ga_{0.8}As cladding layers 38 and 40 in the n-cladding region increases a difference in the optical confinement rate of the active layer between the optical waveguide region and the outside regions, resulting in an increased mode gain difference Δ_{gain}.

The. semiconductor laser device has a buried ridge-shaped optical waveguide for emitting a laser beam of a wavelength at 0.98 micrometers. The mode gain difference and the optical confinement rate are calculated. Δ_{gain}/Γ is 100.42[cm^{-1 1/%] which satisfies the requirement that Δ}_{gain}/Γ is at least 85 [cm⁻¹/%]. The multiple quantum well active layer 44 has two quantum wells, each of which has an optical confinement rate Γ at 0.362% in the fundamental mode. If a cavity length is 890 micrometers, then an average kink output is 289 mW, wherein the width of the stripe-shaped region is 42 micrometers. If a cavity length is 1200 micrometers, then an average kink output is 379 mW, wherein the width of the stripe-shaped region is 42 micrometers.

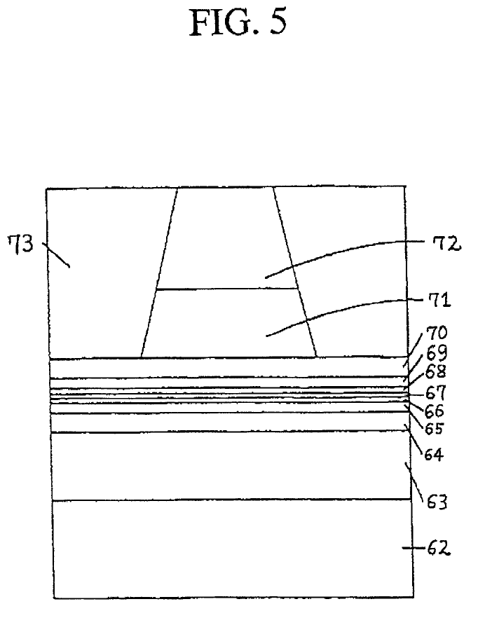

A comparative example 1 will be described with reference to FIG. 5. The semiconductor laser device of this comparative example 1 is identical in structure with the device of the above first embodiment, except for the compositional ratios and thicknesses of individual layers. An n-Al_{0.35}Ga_{0.65}As cladding layer 62 having a thickness of 1000 nanometers is provided in contact directly with an entire region of the top surface of the non-illustrated n-GaAs substrate. An n-Al_{0.15}Ga_{0.85}As cladding layer 63 having a thickness of 450 nanometers is provided in contact directly with an entire region of the top surface of the n-Al_{0.35}Ga_{0.65}As cladding layer 62, An n-Al_{0.35}Ga_{0.65}As cladding layer 64 having a thickness of 200 nanometers is provided in contact directly with an entire region of the top surface of the n-Al_{0.15}Ga_{0.85}As cladding layer 63.

The self confinement hetero-structure active layer has the following multi-layered structure, which varies refractive index in a thickness direction. An n-Al_{0.2}Ga_{0.8}As layer 65 having a thickness of 150 nanometers is provided in contact directly with an entire region of the top surface of the n-cladding region or the n-Al_{0.35}Ga_{0.65}As cladding layer 64. An Al_{0.1}Ga_{0.9}As layer 66 having a thickness of 40 nanometers is provided in contact directly with an entire region of the top surface of the n-Al_{0.2}Ga_{0.8}As layer 65. A double quantum well active layer 67 of InGaAs quantum well layer having a thickness of 4.1 nanometers and GaAs potential barrier layer having a thickness of 5 nanometers is provided in contact directly with an entire region of the top surface of the Al_{0.1}Ga_{0.9}As layer 66. An Al_{0.1}Ga_{0.9}As layer 68 having a thickness of 40 nanometers is provided in contact directly with an entire region of the top surface of the double quantum well active layer 67. A p-Al_{0.2}Ga_{0.8}As layer 69 having a thickness of 150 nanometers is provided in contact directly with an entire region of the top surface of the Al_{0.1}Ga_{0.9}As layer 68.

The p-cladding region has the following multi-layered structure, which varies refractive index in a thickness direction. A p-Al_{0.35}Ga_{0.65}As cladding layer 70 having a thickness of 200 nanometers is provided in contact directly with an entire region of the top surface of the self confinement hetero-structure active layer or the p-Al_{0.2}Ga_{0.8}As layer 69. A mesa-structure is selectively provided on a stripe-shaped region of a top surface of the p-Al_{0.35}Ga_{0.65}As cladding layer 70. The stripe-shaped region defines the optical waveguide region. The mesa-structure comprises the following double-layered structure. A p-Al_{0.15}Ga_{0.85}As cladding layer 71 having a thickness of 400 nanometers is provided in contact directly with the stripe-shaped region of the top surface of the p-Al_{0.35}Ga_{0.65}As cladding layer 70. The p-Al_{0.15}Ga_{0.85}As cladding layer 71 has a ridge-shape. A p-Al_{0.35}Ga_{0.65}As cladding layer 72 having a thickness of 1000 nanometers is provided in contact directly with a top surface of the p-Al_{0.15}Ga_{0.85}As cladding layer 71. The p-Al_{0.35}Ga_{0.65}As cladding layer 72 has a ridge-shape.

Further, n-Al_{0.35}Ga_{0.65}As current blocking layers 73 are provided in contact directly with opposite side regions of the top surface of the p-Al_{0.35}Ga_{0.65}As cladding layer 70 and also in contact directly with sloped side faces of the mesa-structure, wherein the opposite side regions extend in opposite sides of the stripe-shaped region.

The semiconductor laser device has a buried ridge-shaped optical waveguide for emitting a laser beam of a wavelength at 0.98 micrometers. The mode gain difference and the optical confinement rate are calculated. Δ_{gain}/Γ is 72.26[cm−1/%] which does not satisfy the requirement that Δ_{gain}/Γ is at least 85 [cm−1/%]. An average kink output is 226 mW.

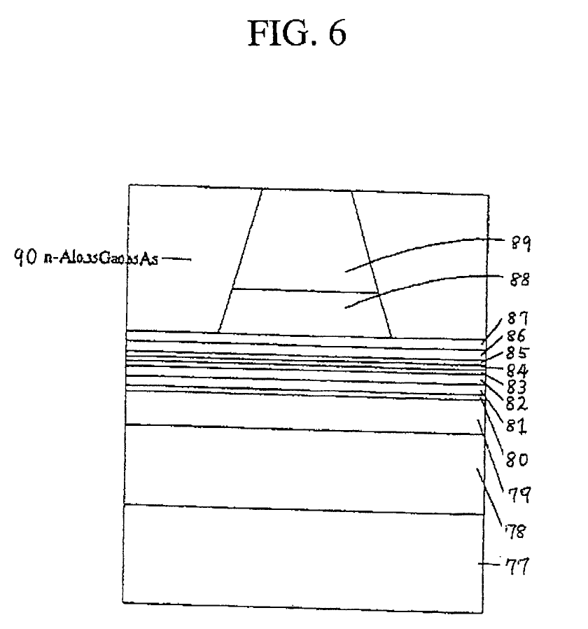

A comparative example 2 will be described with reference to FIG. 6. The semiconductor laser device of this comparative example 2 is identical in structure with the device of the above third embodiment, except for the compositional ratios and thicknesses of individual layers. An n-Al_{0.35}Ga_{0.65}As cladding layer 77 having a thickness of 1000 nanometers is provided in contact directly with an entire region of the top surface of the non-illustrated n-GaAs substrate. An n-Al_{0.2}Ga_{0.8}As cladding layer 78 having a thickness of 600 nanometers is provided in contact directly with an entire region of the top surface of the n-Al_{0.35}Ga_{0.65}As cladding layer 77. An n-Al_{0.15}Ga_{0.85}As cladding layer 79 having a thickness of 200 nanometers is provided in contact directly with an entire region of the top surface of the n-Al_{0.2}Ga_{0.8}As cladding layer 78. An n-Al_{0.2}Ga_{0.8}As cladding layer 80 having a thickness of 700 nanometers is provided in contact directly with an entire region of the top surface of the n-Al_{0.15}Ga_{0.85}As cladding layer 79. An n-Al_{0.35}Ga_{0.65}As cladding layer 81 having a thickness of 70 nanometers is provided in contact directly with an entire region of the top surface of the n-Al_{0.2}Ga_{0.8}As cladding layer 80.

The self confinement hetero-structure active layer has the following multi-layered structure, which varies refractive index in a thickness direction. An n-Al_{0.2}Ga_{0.8}As layer 82 having a thickness of 100 nanometers is provided in contact directly with an entire region of the top surface of the n-cladding region or the n-Al_{0.35}Ga_{0.65}As cladding layer 81. An Al_{0.1}Ga_{0.9}As layer 83 having a thickness of 65 nanometers is provided in contact directly with an entire region of the top surface of the n-Al_{0.2}Ga_{0.8}As layer 82. A double quantum well active layer 84 of InGaAs quantum well layer having a thickness of 4.1 nanometers and GaAs potential barrier layer having a thickness of 5 nanometers is provided in contact directly with an entire region of the top surface of the Al_{0.1}Ga_{0.9}As layer 83. An Al_{0.1}Ga_{0.9}As layer 85 having a thickness of 65 nanometers is provided in contact directly with an entire region of the top surface of the double quantum well active layer 84. A p-Al_{0.2}Ga_{0.8}As layer 86 having a thickness of 100 nanometers is provided in contact directly with an entire region of the top surface of the Al_{0.1}Ga_{0.9}As layer 85.

The p-cladding region has the following multi-layered structure, which varies refractive index in a thickness direction. A p-Al_{0.35}Ga_{0.65}As cladding layer 87 having a thickness of 100 nanometers is provided in contact directly with an entire region of the top surface of the self confinement hetero-structure active layer or the p-Al_{0.2}Ga_{0.8}As layer 86. A mesa-structure is selectively provided on a stripe-shaped region of a top surface of the p-Al_{0.35}Ga_{0.65}As cladding layer 87. The stripe-shaped region defines the optical waveguide region. The mesa-structure comprises the following double-layered structure. A p-Al_{0.15}Ga_{0.85}As cladding layer 88 having a thickness of 375 nanometers is provided in contact directly with the stripe-shaped region of the top surface of the p-Al_{0.35}Ga_{0.65}As cladding layer 87. The p-Al_{0.15}Ga_{0.85}As cladding layer 88 has a ridge-shape. A p-Al_{0.35}Ga_{0.65}As cladding layer 89 having a thickness of 1000 nanometers is provided in contact directly with a top surface of the p-Al_{0.15}Ga_{0.85}As cladding layer 88. The p-Al_{0.35}Ga_{0.65}AS cladding layer 89 has a ridge-shape.

Further, n-Al_{0.35}Ga_{0.65}As current blocking layers 90 are provided in contact directly with opposite side regions of the top surface of the p-Al_{0.35}Ga_{0.65}As cladding layer 87 and also in contact directly with sloped side faces of the mesa-structure, wherein the opposite side regions extend in opposite sides of the stripe-shaped region,

The semiconductor laser device has a buried ridge-shaped optical waveguide for emitting a laser beam of a wavelength at 0.98 micrometers. The mode gain difference and the optical confinement rate arc calculated. Δ_{gain}/Γ is 61.66[cm−1/] which does not satisfy the requirement that Δ_{gain}/Γ is at least 85 [cm−1/%]. An average kink output is 153 mW.

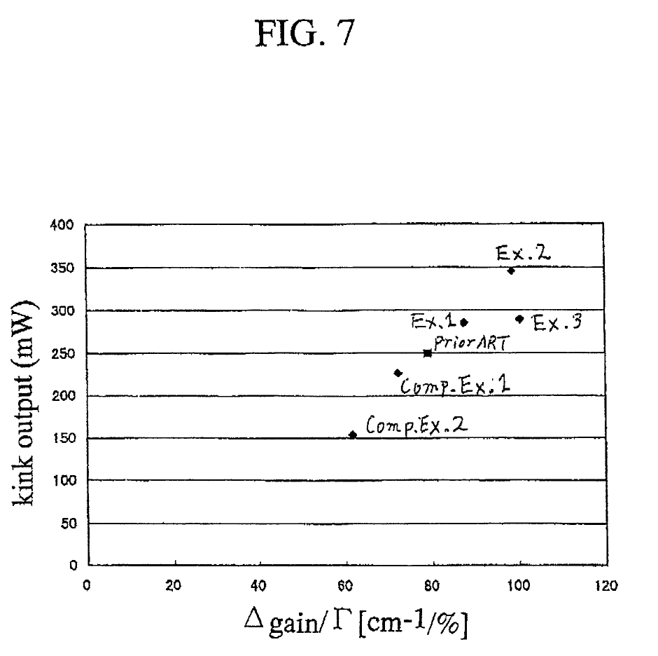

A relative relationship between Γ_{gain}Γ and kink output will be described with reference to FIG. 7. The Δ_{gain}/Γ and kink output has a strong and matured relative relationship with reference particularly to the examples 1 and 2 and the comparative examples 1 and 2 as well as the applicant's admitted prior art. The kink output is generally proportional to Δ_{gain}/Γ. If Δ_{gain}/ Γ is 80[cm⁻¹/%], then the kink output is only 250 (mW). If a higher kink output than 250 (mW) is necessary, then it is necessary that Δ_{gain}/Γ is at least 85[cm⁻¹/%].

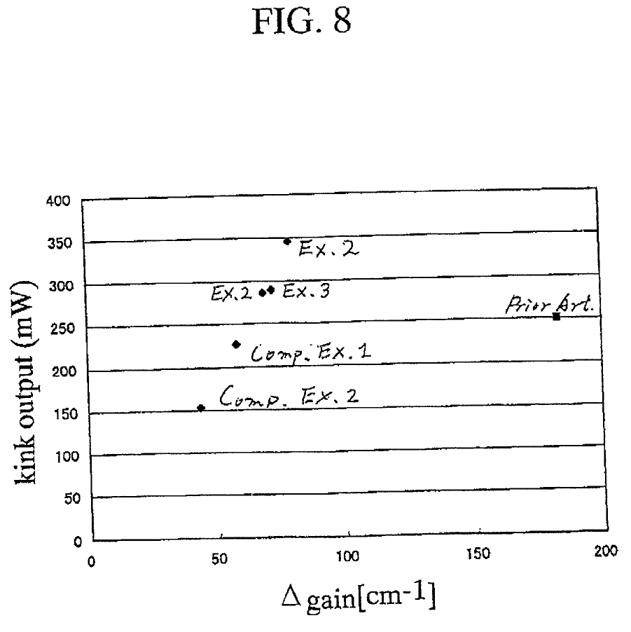

With reference to FIG. 8, the mode gain difference Δ_{gain} and kink output has a weak and immature relative relationship. Namely, the kink output does not maturely depend on the mode gain difference Δ_{gain} only, and rather does maturely depend on Δ_{gain}/Γ. If only the mode gain difference Δ_{gain} is increased, then it is uncertain that the kink output is increased. If both the mode gain difference Δ_{gain} and the optical confinement rate Γ are increased, then the kink output is not increased. If the mode gain difference Δ_{gain} is increased and the optical confinement rate Γ is decreased, then the kink output is increased. Accordingly, in order to obtain an increased kink output, it is essential that Δ_{gain}/Γ is increased.

Although the invention has been described above in connection with several preferred embodiments therefor, it will be appreciated that those embodiments have been provided solely for illustrating the invention, and not in a limiting sense. Numerous modifications and substitutions of equivalent materials and techniques will be readily apparent to those skilled in the art after reading the present application, and all such modifications and substitutions are expressly understood to fall within the true scope and spirit of the appended claims.

What is claimed is:

1. A semiconductor laser device having at least an active layer and an optical waveguide region, which includes at least a part of said active layer,
wherein Δ_{gain}/Γ is at least 85 [cm⁻¹/%], where 66 gain [cm⁻¹] is a difference in gain between a zero-order fundamental mode and a one-order high-order mode in a lateral transverse mode of said optical waveguide, and Γ[%] is a total optical confinement rate of said at least part of said active layer in said zero-order fundamental mode.

2. The device as claimed in claim 1, wherein said at least one active layer comprises plural active layers, and said Γ [%]is a total sum of individual optical confinement rates of said plural active layers.

3. The device as claimed in claim 2, wherein said plural active layers comprise multiple quantum well layers, and said at least part of each of said multiple quantum well layers has an optical confinement rate of at most 0.5% in said zero-order fundamental mode.

4. The device as claimed in claim 1, wherein said at least one active layer has a separate confinement hetero-structure, and said Γ [%] is an optical confinement rate of said at least part of said separate confinement hetero-structure.

5. The device as claimed in claim 1, wherein said optical waveguide region has a symmetrical refractive index profile with reference to said at least one active layer in a vertical direction to interfaces of said at least one active layer.

6. The device as claimed in claim 1, wherein said optical waveguide region has an asymmetrical refractive index profile with reference to said at least one active layer in a vertical direction to interfaces of said at least one active layer.

7. The device as claimed in claim 6, wherein said device has an n-side region and a p-side region, which are separated by said at least one active layer, and said asymmetrical refractive index profile is that said n-side region is higher than said p-side region in an integrated value of a refractive index in said vertical direction.

8. The device as claimed in claim 1, further comprising at least a cladding region adjacent to at least one interface of said at least one active layer, and wherein said at least cladding region comprises a plural-layered structure, which includes at least an optical confinement layer.

9. The device as claimed in claim 8, wherein said at least cladding region comprises p-side and n-side. cladding regions adjacent to opposite surfaces of said at least one active layer, and each of said p-side and n-side cladding regions comprises a plural-layered structure, which includes at least an optical confinement layer.

10. The device as claimed in claim 9, wherein said at least one active layer and said p-side and n-side cladding regions have a symmetrical refractive index profile with reference to said at least one active layer in a vertical direction to said interfaces of said at least one active layer,

11. The device as claimed in claim 9, wherein said at least one active layer and said p-side and n-side cladding regions have an asymmetrical refractive index profile with reference to said at least one active layer in a vertical direction to said interfaces of said at least one active layer.

12. The device as claimed in claim 11, wherein said asymmetrical refractive index profile is that said n-side cladding region is higher than said p-side cladding region in an integrated value of a refractive index in said vertical direction.

13. The device as claimed in claim 1, wherein said device has a ridged waveguide structure, and a partial region of said at least one active layer is included in said optical waveguide region.

14. The device as claimed in claim 13, further comprising current blocking layers in both sides of said ridged waveguide structure.

15. The device as claimed in claim 1, wherein said device has a self-aligned structure, and a partial region of said active layer is included in said optical waveguide region.

16. The device as claimed in claim 1, further comprising current confinement layers in both sides of said at least one active layer, and substantially all regions of said active layer is included in said optical waveguide region.

17. The device as claimed in claim 1, further comprising:
a bottom cladding region under said at least one active layer;
a top cladding region over said at least one active layer, and said top cladding region having a stripe-shaped region, which defmes said optical waveguide region; and
current blocking layers adjacent to both sides of said stripe-shaped region.

18. The device as claimed in claim 17, wherein said optical waveguide region is a ridge-type optical waveguide.

19. The device as claimed in claim 17, wherein said optical waveguide region is a self-aligned structure optical waveguide.

20. The device as claimed in claim 17, wherein said bottom cladding region has a first multi-layered structure comprising plural layers different in reflexive index, and said top cladding region has a second multi-layered structure comprising other plural layers different in reflexive index.

21. The device as claimed in claim 1, further comprising:
a bottom cladding region under said at least one active layer, said bottom cladding region comprising a first plural-layered structure different in refractive index and including at least a first optical confinement cladding layer having a higher refractive index; and
a top cladding region over said at least one active layer, said top cladding region also having a ridge structure having a stripe-shape region which defines said optical waveguide region, and said top cladding region comprising a second plural-layered structure different in refractive index and including at least a second optical confinement cladding layer having a higher refractive index, and said second optical confinement cladding layer selectively extending in said ridge structure, wherein an inside of said optical waveguide region has a symmetrical refractive index profile with reference to said at least one active layer in a vertical direction to surfaces of said at least one active layer, whilst an outside of said optical waveguide region has an asymmetrical refractive index profile with reference to said at least one active layer in said vertical direction.

22. The device as claimed in claim 21, further comprising: current blocking layers adjacent to both sides of said ridge structure.

23. The device as claimed in claim 1, further comprising:
a bottomn cladding region under said at least one active layer, said bottom cladding region comprising a first plural-layered structure different in refractive index and including at least a first optical confinement cladding layer having a higher refractive index; and
a top cladding region over said at least one active layer, said top cladding region also having a ridge structure having a stripe-shape region which defines said optical waveguide region, and said top cladding region comprising a second plural-layered structure different in refractive index and including at least a second optical confinement cladding layer having a higher refractive index, and said second optical confinement cladding layer selectively extending in said ridge structure,
wherein an inside of said optical waveguide region has a symmetrical optical confinement rate profile with reference to said at least one active layer in a vertical direction to surfaces of said at least one active layer, whilst an outside of said optical waveguide region has an asymmetrical optical confinement rate profile with reference to said at least one active layer in said vertical direction, and
wherein said inside of said optical waveguide region is higher than said outside of said optical waveguide region in an optical confinement rate of said at least one active layer.

24. The device as claimed in claim 23, further comprising: current blocking layers adjacent to both sides of said ridge structure.

25. A semiconductor laser device comiprising:
at least an active layer;
a bottom cladding region under said at least one active layer, said bottom cladding region comprising a first plural-layered structure different in refractive index and including at least a first optical confinement cladding layer having a higher refractive index; and
a top cladding region over said at least one active layer, said top cladding region also having a ridge structure having a stripe-shape region which defines an optical waveguide region, and said top cladding region comprising a second plural-layered structure different in refractive index and including at least a second optical confinement cladding layer having a higher refractive index, and said second optical confinement cladding layer selectively extending in said ridge structure,
wherein an inside of said optical waveguide region has a symmetrical refractive index profile with reference to said at least one active layer in a vertical direction to surfaces of said at least one active layer, whilst an outside of said optical waveguide region has an asymmetrical refractive index profile with reference to said at least one active layer in said vertical direction.

26. The device as claimed in claim 25, further comprising: current blocking layers adjacent to both sides of said ridge structure.

27. The device as claimed in claim 25, wherein Δ_{gain}/Γ is at least 85 [cm^{31 1}/%], where Δ gain [cm^{31 1}] is a difference in gain between a zero-order fundamental mode and a one-order high-order mode in a lateral transverse mode of said optical waveguide, and Γ [%] is a total optical confinement rate of said at least part of said active layer in said zero-order fundamental mode.

28. A semiconductor laser device comprising:
at least an active layer;
a bottom cladding region under said at least one active layer, said
bottom cladding region comprising a first plural-layered structure different in refractive index and including at least a first optical confinement cladding layer having a higher refractive index; and
a top cladding region over said at least one active layer, said top cladding region also having a ridge structure having a stripe-shape region which defines an optical waveguide region, and said top cladding region comprising a second plural-layered structure different in refractive index and including at least a second optical confinement cladding layer having a higher refractive index, and said second optical confinement cladding layer selectively extending in said ridge structure,
wherein an inside of said optical waveguide region has a symmetrical optical confinement rate profile with reference to said at least one active layer in a vertical direction to surfaces of said at least one active layer, whilst an outside of said optical waveguide region has an asymmetrical optical confinement rate profile with reference to said at least one active layer in said vertical direction, and wherein said inside of said optical waveguide region is higher than said outside of said optical waveguide region in an optical confinement rate of said at least one active layer.

29. The device as claimed in claim 28, further comprising: current blocking layers adjacent to both sides of said ridge structure.

30. The device as claimed in claim 28, wherein Δ_{gain}/Γ is at least 85 [cm⁻¹/%], where Δ gain [cm⁻¹]is a difference in gain between a zero-order fundamental mode and a one-order high-order mode in a lateral transverse mode of said optical waveguide, and Γ [%] is a total optical confinement rate of said at least part of said active layer in said zero-order fundamental mode.
